(19) United States
(12) Patent Application Publication
(10) Pub. No.: US 2024/0387174 A1
(43) Pub. Date: Nov. 21, 2024

(54) FORMATION OF SILICON-AND-METAL-CONTAINING MATERIALS FOR HARDMASK APPLICATIONS

(71) Applicant: Applied Materials, Inc., Santa Clara, CA (US)

(72) Inventors: Guangyan Zhong, Sunnyvale, CA (US); Eswaranand Venkatasubramanian, Santa Clara, CA (US); Rui Cheng, San Jose, CA (US); Santhosh Kiran Rajarajan, Sunnyvale, CA (US); Ganesh Balasubramanian, Fremont, CA (US); Abhijit Basu Mallick, Sunnyvale, CA (US); Karthik Janakiraman, San Jose, CA (US); Guoqing Li, Santa Clara, CA (US)

(73) Assignee: Applied Materials, Inc., Santa Clara, CA (US)

(21) Appl. No.: 18/197,528

(22) Filed: May 15, 2023

(51) Int. Cl. H01L 21/033

(52) U.S. Cl. CPC H01L 21/0332; H01L 21/0337

(57) ABSTRACT

Exemplary methods of semiconductor processing may include providing deposition precursors to a processing region of a semiconductor processing chamber. The deposition precursors may include a silicon-and-halogen-containing precursor and a metal-containing precursor. A substrate may be housed within the processing region. The methods may include generating plasma effluents of the deposition precursors. The methods may include forming a layer of silicon-and-metal-containing material on the substrate.

### TECHNICAL FIELD

The present technology relates to semiconductor processes and equipment. More specifically, the present technology relates to methods of depositing silicon-and-metal-containing materials that may be used as hardmask materials.

### BACKGROUND

Integrated circuits are made possible by processes which produce intricately patterned material layers on substrate surfaces. Producing patterned structures on a substrate requires controlled methods of formation and removal of exposed material. As device sizes continue to shrink, and structures become more complex, material properties may affect subsequent operations. For example, hardmask materials may affect both the ability to develop structures as well as the ability to selectively remove materials.

Thus, there is a need for improved systems and methods that can be used to produce high quality devices and structures. These and other needs are addressed by the present technology.

### SUMMARY

Exemplary methods of semiconductor processing may include providing deposition precursors to a processing region of a semiconductor processing chamber. The deposition precursors may include a silicon-and-halogen-containing precursor and a metal-containing precursor. A substrate may be housed within the processing region. The methods may include generating plasma effluents of the deposition precursors. The methods may include forming a layer of silicon-and-metal-containing material on the substrate.

In some embodiments, the silicon-and-halogen-containing precursor comprises silicon tetrafluoride (SiF₄). The metal-containing precursor may include one or more of tungsten, molybdenum, cobalt, tantalum, ruthenium, titanium, rhenium, hafnium, or zirconium. The metal-containing precursor may further include a halogen. The deposition precursors may further include one or more of a boron-containing precursor, a carbon-containing precursor, or a nitrogen-containing precursor. The methods may include cycling a flow rate of the deposition precursors. A flow rate of the metal-containing precursor may be greater than a flow rate of the silicon-and-hydrogen-containing precursor during a first period of time. The flow rate of the metal-containing precursor may be less than a flow rate of the silicon-and-hydrogen-containing precursor during a second period of time. The layer of silicon-and-metal-containing material may be characterized by a metal concentration of greater than or about 20 at. %. The methods may include pre-treating the substrate prior to forming the layer of silicon-and-metal-containing material. Pre-treating the substrate may include providing a nitrogen-containing precursor to the processing region of the semiconductor processing chamber, generating plasma effluents of the nitrogen-containing precursor, and contacting the substrate with the plasma effluents of the nitrogen-containing precursor. The methods may include, subsequent pre-treating the substrate, forming a seed layer on the substrate. The seed layer may be or include an amorphous boron-containing material.

Some embodiments of the present technology may encompass semiconductor processing methods. The methods may include providing deposition precursors to a processing region of a semiconductor processing chamber. The deposition precursors may include a silicon-and-halogen-containing precursor and a metal-containing precursor. A substrate may be housed within the processing region. The methods may include generating plasma effluents of the deposition precursors. Plasma effluents of the deposition precursors may be generated at a plasma power of greater than or about 200 W. The methods may include forming a layer of silicon-and-metal-containing material on the substrate.

In some embodiments, plasma effluents of the deposition precursors may be generated at a plasma power of less than or about 2,000 W. The layer of silicon-and-metal-containing material may be free of fluorine, oxygen, or both. The methods may include, prior to providing the deposition precursors, pre-treating the substrate and forming a seed layer on the substrate. A temperature within the processing region may be maintained at less than or about 600° C. A pressure within the processing region may be maintained at less than or about 50 Torr.

Some embodiments of the present technology may encompass semiconductor processing methods. The methods may include providing a silicon-containing precursor and a metal-containing precursor to a processing region of a semiconductor processing chamber. A substrate may be housed within the processing region. The methods may include forming a layer of silicon-and-metal-containing material on the substrate. The layer of silicon-and-metal-containing material may be characterized by a metal concentration of greater than or about 20 at. %.

In some embodiments, the silicon-containing precursor may be or include silicon tetrafluoride (SiF₄) and the metal-containing precursor may be or include tungsten hexafluoride (WF₆). The layer of silicon-and-metal-containing material may be formed at a rate of greater than or about 500 Å/m.

Such technology may provide numerous benefits over conventional systems and techniques. For example, the processes may produce silicon-and-metal-containing materials that may be characterized by a wide range of metal concentration. Additionally, the processes may utilize deposition precursors that may not spontaneously react prior to deposition, or may have minimal reaction prior to deposition. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2A shows a schematic cross-sectional view of an exemplary processing chamber according to some embodiments of the present technology.

FIG. 2B shows a detailed view of a portion of the processing chamber illustrated in FIG. 2A according to some embodiments of the present technology.

FIG. 3 shows a bottom plan view of an exemplary showerhead according to some embodiments of the present technology.

FIG. 4 shows exemplary operations in a method according to some embodiments of the present technology.

FIGS. 5A-5B show cross-sectional views of substrates being processed according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include additional or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During semiconductor fabrication, structures may be produced on a substrate utilizing a variety of deposition and etching operations. Hardmask materials may be used to allow materials to be at least partially etched to produce features across the substrate. As device sizes continue to reduce, and improved selectivity between materials may ease structural formation, utilizing improved hardmasks may facilitate fabrication. For example, future DRAM nodes may require taller capacitor structures, which may involve forming deeper trenches on a substrate. Conventional hardmasks may reach a limitation in selectivity relative to underlying silicon materials. Accordingly, many semiconductor fabrication processes are utilizing thicker hardmask films for larger vertical device structures, or attempting to develop hardmask materials characterized by increased hardness. However, while a hardmask may be characterized by a sufficient transparency at one thickness, as the thickness increases, the film may become less transparent. When a film becomes sufficiently opaque, processes may require additional operations to open areas near alignment markers to ensure correct orientation. Additionally, thicker hardmask films may challenge patterning, which may in turn affect uniformity of transfer into the underlying structure.

The present technology may overcome these limitations by producing hardmask materials that incorporate both silicon and one or more metals. Although these materials may counterintuitively reduce transparency and hardness, the materials may be more selective to underlying materials, which may afford reduced thickness hardmasks, and which overall may improve etching and structural formation in semiconductor substrates. It is to be understood that the present technology is not intended to be limited to the specific films and processing discussed, as the techniques described may be used to improve a number of film formation processes, and may be applicable to a variety of processing chambers and operations.

Although the remaining disclosure will routinely identify specific deposition processes utilizing the disclosed technology, it will be readily understood that the systems and methods are equally applicable to deposition and cleaning processes as may occur in the described chambers. Accordingly, the technology should not be considered to be so limited as for use with the exemplary deposition processes or chambers alone. Moreover, although an exemplary chamber is described to provide foundation for the present technology, it is to be understood that the present technology can be applied to virtually any semiconductor processing chamber that may allow the operations described.

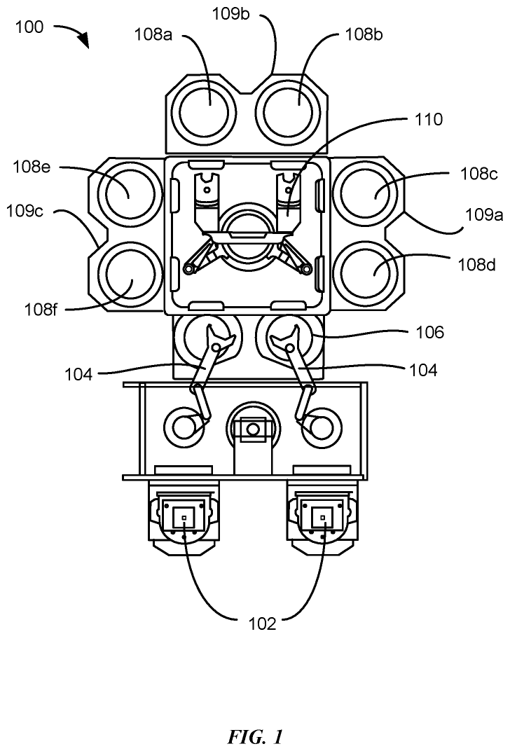

FIG. 1 shows a top plan view of one embodiment of a processing system 100 of deposition, etching, baking, and curing chambers according to embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

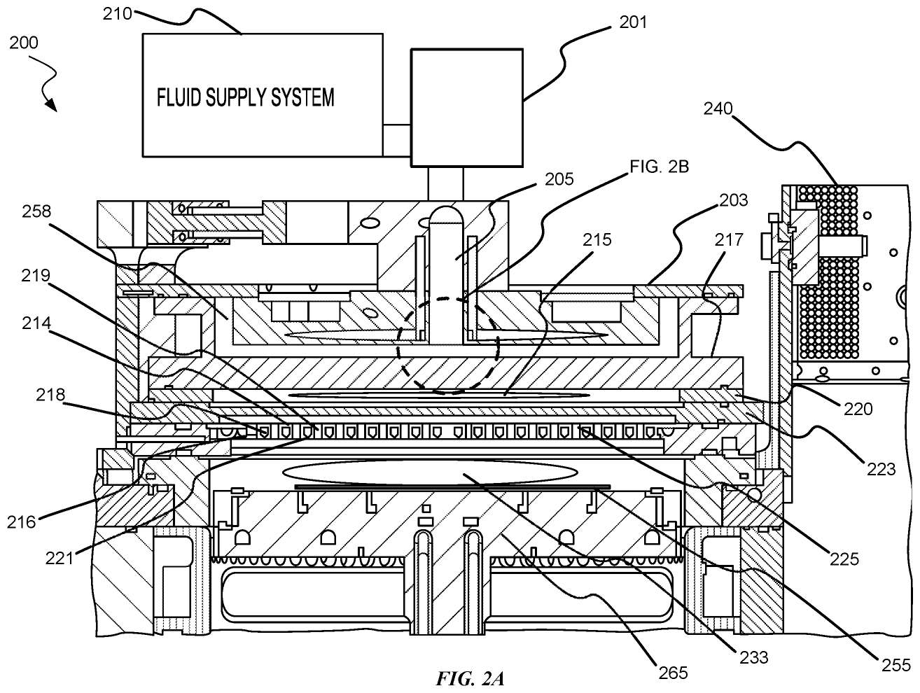

FIG. 2A shows a cross-sectional view of an exemplary processing system 200 with partitioned plasma generation regions within the processing chamber. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system (RPS) 201 may optionally be included in the system, and may process a first gas which then travels through gas inlet assembly 205. The inlet assembly 205 may include two or more distinct gas supply channels where the second channel (not shown) may bypass the RPS 201, if included.

A cooling plate 203, faceplate 217, ion suppressor 223, showerhead 225, and a pedestal 265 or substrate support, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may include aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiNx:SiOx etch ratios, Si:SiOx etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being treated. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which, for example, oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the deposition or etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

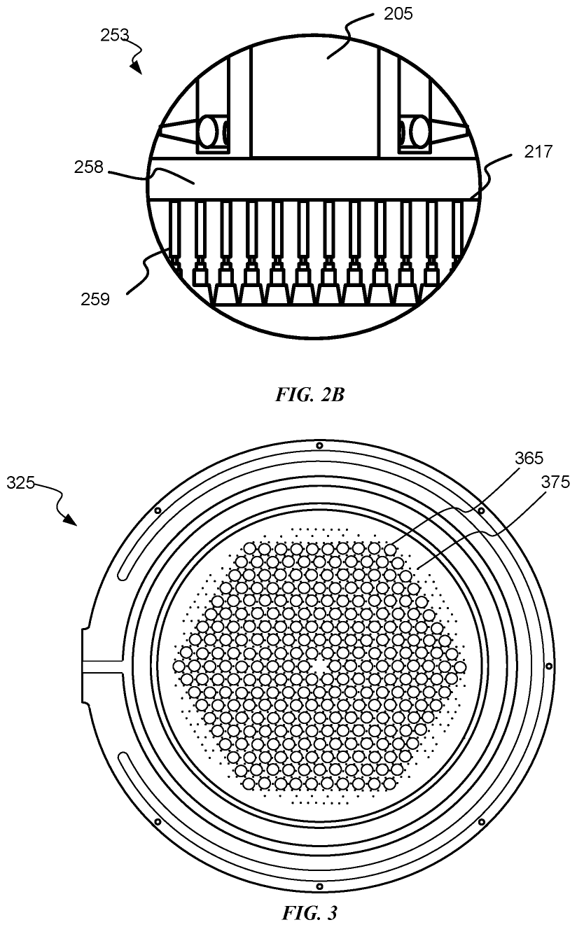

The gas distribution assemblies such as showerhead 225 for use in the processing system 200 may be referred to as dual channel showerheads (DCSH) and are additionally detailed in the embodiments described in FIG. 3. The dual channel showerhead may provide for processes that allow for separation of precursors outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the showerhead 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

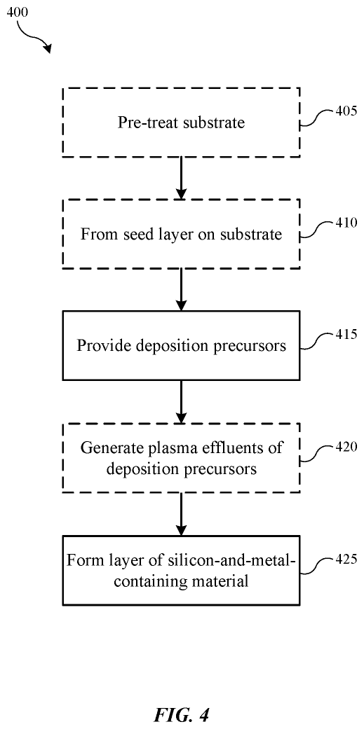

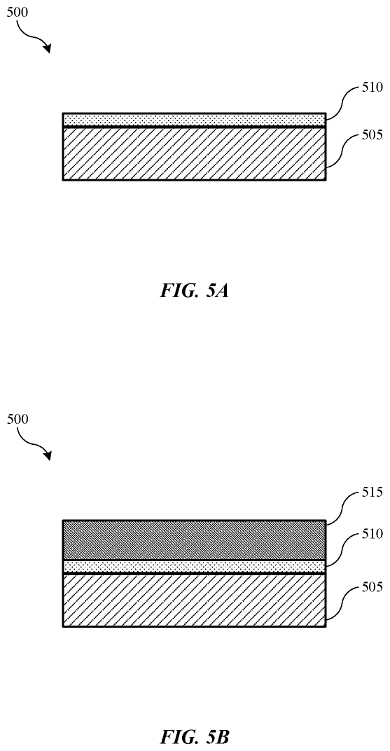

FIG. 4 shows exemplary operations in a method 400 according to some embodiments of the present technology. The method may be performed in a variety of processing chambers, including one of processing chamber 108a-f or processing system 200 described above. Method 400 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 400 may describe operations shown schematically in FIGS. 5A-5B, the illustrations of which will be described in conjunction with the operations of method 400. It is to be understood that the figures illustrate only partial schematic views, and a substrate may contain any number of additional materials and features having a variety of characteristics and aspects as illustrated in the figures.

Method 400 may include additional operations prior to initiation of the listed operations. For example, additional processing operations may include forming structures on a semiconductor substrate, which may include both forming and removing material. Prior processing operations may be performed in the chamber in which method 400 may be performed, or processing may be performed in one or more other processing chambers prior to delivering the substrate into the semiconductor processing chamber in which method 400 may be performed. Regardless, method 400 may optionally include delivering a substrate 505 to a processing region of a semiconductor processing chamber, such as one of processing chamber 108a-f or processing system 200 described above, or other chambers that may include components as described above. The substrate 505 may be deposited on a substrate support, which may be a pedestal such as pedestal 265 described above, and which may reside in a processing region of the chamber, such as volume 218 described above.

The substrate 505 may be or include any number of materials on which materials may be deposited. The substrate 505 may be or include silicon, germanium, dielectric materials including silicon oxide or silicon nitride, metal materials, or any number of combinations of these materials, which may be the substrate, or materials formed on the substrate. In some embodiments optional treatment operations, such as a pre-treatment at optional operation 405, may be performed to prepare a surface of the substrate 505 for deposition. For example, a pre-treatment may be performed to provide certain ligand terminations on the surface of the substrate 505, and which may facilitate nucleation of a film to be deposited. For example, hydrogen, oxygen, carbon, nitrogen, or other molecular terminations, including any combination of these atoms or radicals, may be adsorbed, reacted, or formed on a surface of the substrate 505. In embodiments, a pre-treatment precursor may be provided to the processing region and plasma effluents may be generated. The substrate 505 may be contacted with the plasma effluents of the pre-treatment precursor to introduce said ligand terminations on the surface of the substrate 505. In one exemplary embodiment, the pre-treatment precursor may include diatomic hydrogen (H₂), diatomic nitrogen (N₂), or both, as well as any other hydrogen-containing precursor or nitrogen-containing precursor useful in semiconductor processing. In order to introduce sufficient ligand terminations, a flow rate of the pre-treatment precursor may be greater than or about 100 sccm, and may be greater than or about 250 sccm, greater than or about 500 sccm, greater than or about 750 sccm, greater than or about 1,000 sccm, greater than or about 2,000 sccm, greater than or about 3,000 sccm, greater than or about 4,000 sccm, greater than or about 5,000 sccm, or more. Further, the plasma effluents may be generated at a plasma power of greater than or about 250 W, greater than or about 500 W, greater than or about 550 W, greater than or about 600 W, greater than or about 650 W, greater than or about 700 W, or more. Additionally, material removal may be performed, such as reduction of native oxides or etching of material, or any other operation that may prepare one or more exposed surfaces of the substrate 505 for deposition.

As shown in FIG. 5A, subsequent the optional pre-treatment, method 400 may include forming a seed layer 510 on the substrate 505 at optional operation 410. The seed layer 510 may increase film adhesion between adjacent layers of material. Forming the seed layer 510 may include providing a seed layer precursor may be provided to the processing region and plasma effluents may be generated. The substrate 505 may be contacted with the plasma effluents of the seed layer precursor to form the seed layer 510 on the surface of the substrate 505. In embodiments where the pre-treatment at optional operation 405 provides nitrogen ligand terminations, the seed layer 510 may include hydrogen. The hydrogen in the seed layer 510 may strongly bond with both the nitrogen ligand terminations as well as the layer of silicon-and-metal-containing material to be subsequently formed. In one exemplary embodiment, the seed layer 510 may include an amorphous boron-containing material. The seed layer 510 may be formed by using a boron-containing precursor as the seed layer precursor. The boron-containing precursor may be any boron-containing material useful in semiconductor processing, such as diborane (B₂H₆). The seed layer precursor may also be provided with one or more inert or carrier gases. A flow rate of the seed layer precursor may be greater than or about 100 sccm, and may be greater than or about 250 sccm, greater than or about 500 sccm, greater than or about 750 sccm, greater than or about 1,000 sccm, or more. Further, the plasma effluents may be generated at a plasma power of greater than or about 100 W, greater than or about 200 W, greater than or about 250 W, greater than or about 300 W, greater than or about 500 W, greater than or about 750 W, greater than or about 1,000 W, greater than or about 1,500 W, or more. As previously discussed, strong bonding between nitrogen present on the pre-treated surface of the substrate 505 and hydrogen present in the seed layer 510 may promote film adhesion for the subsequently formed layer of silicon-and-metal-containing material.

At operation 415, one or more deposition precursors may be delivered to the processing region of the semiconductor processing chamber. For example, the film being deposited may be a hardmask film used in semiconductor processing. The deposition precursors may include any number of hardmask precursors, including one or more silicon-and-halogen-containing precursors, one or more metal-containing precursors, one or more boron-containing precursors, one or more-carbon-containing precursors, and/or one or more nitrogen-containing precursors. The precursors may be flowed together. However, it is also contemplated that one or more of the deposition precursors may be flowed such that they remain fluidly isolated from other deposition precursors prior to reaching the processing region. For example, in exemplary embodiments in which a silicon-and-metal-containing film may be formed, at least one silicon-and-halogen-containing precursor and at least one metal-containing precursor may be delivered to the processing region of the semiconductor processing chamber. Plasma enhanced deposition may be performed in some embodiments of the present technology, which may facilitate material reactions and deposition. For example, at optional operation 420, plasma effluents may be generated of the deposition precursors, and a layer of silicon-and-metal-containing material 515 may be deposited at operation 425 as shown in FIG. 5B.

Depending on the precursors used, a flow rate of the deposition precursors may be used to control incorporation of silicon and metal in the layer of silicon-and-metal-containing material 515. For example, a flow rate of the one or more silicon-and-halogen-containing precursors may be greater than or about 50 sccm, and may be greater than or about 75 sccm, greater than or about 100 sccm, greater than or about 125 sccm, greater than or about 150 sccm, greater than or about 175 sccm, greater than or about 200 sccm, greater than or about 225 sccm, greater than or about 250 sccm, greater than or about 275 sccm, greater than or about 300 sccm, greater than or about 400 sccm, greater than or about 500 sccm, or more. Similarly, the flow rate of the one or more silicon-and-halogen-containing precursors may be less than or about 750 sccm, and may be less than or about 500 sccm, less than or about 400 sccm, less than or about 300 sccm, or less. A flow rate of the one or more metal-containing precursors may be greater than or about 2 sccm, and may be greater than or about 4 sccm, greater than or about 6 sccm, greater than or about 8 sccm, greater than or about 10 sccm, greater than or about 15 sccm, greater than or about 20 sccm, greater than or about 50 sccm, or more. Similarly, the flow rate of the one or more metal-containing precursors may be less than or about 50 sccm, and may be less than or about 40 sccm, less than or about 30 sccm, less than or about 20 sccm, or less.

Any number of deposition precursors may be used with the present technology with regard to the one or more silicon-and-halogen-containing precursors. Exemplary silicon-and-halogen-containing precursors may include silicon tetrafluoride (SiF₄), trifluorosilane (SiF₃H), difluorosilane (SiF₂H₂), as well as any other silicon-and-halogen-containing materials that may be used to produce silicon-and-metal-containing materials. The silicon incorporation in the produced film may be based on any percentage incorporation. For example, the produced film may include greater than or about 5 at. % silicon incorporation, and in some embodiments may include greater than or about 10 at. % silicon incorporation, greater than or about 60% silicon incorporation, greater than or about 65% silicon incorporation, greater than or about 70% silicon incorporation, greater than or about 75% silicon incorporation, greater than or about 80% silicon incorporation, greater than or about 85% silicon incorporation, greater than or about 90% silicon incorporation, greater than or about 95% silicon incorporation, or greater, including a film that is substantially or essentially silicon, less the amount of metal within the material. Although trace materials from exposure to atmosphere or other process environments may be incorporated within the material, it is to be understood that the material may still be essentially silicon-and-metal-based in nature.

The one or more metal-containing precursors may include any metal-containing precursor, such as including any metal or transition metal that may be delivered to the processing region in a stable form. Exemplary metal-containing precursors may include one or more of tungsten, molybdenum, cobalt, tantalum, ruthenium, titanium, rhenium, hafnium, zirconium, or any other metal or transition metal that may be incorporated with silicon in a hardmask material. Exemplary metal-containing precursors may also include one or more halogens, such as fluorine, chlorine, bromine, or iodine. Metal-containing precursors may include any number of metal-containing materials, which may be dissociated in plasma to provide the metal for incorporation.

For example, non-limiting examples of metal-containing precursors that may be used in embodiments of the present technology may include tungsten hexafluoride (WF₆), tungsten hexacarbonyl (W(CO)₆), molybdenum hexafluoride (MoF₆), molybdenum pentachloride (MoCl₅), molybdenum hexacarbonyl (Mo(CO)₆), titanium tetrachloride (TiCl₄), tetrakis(dimethylamido)titanium (C₈H₂₄N₄Ti), titanium tetrafluoride (TiF₄), trimethylaluminum (Al₂(CH₃)₆), aluminum chloride (AlCl₃), cobaltocene (Co(C₅H₅)₂), tantalum pentachloride (TaCl₅), or any other metal-containing precursor that may be used to provide a metal material for incorporation in a silicon-and-metal-containing material.

One or more additional deposition precursors may be provided. For example, in some embodiments, the layer of silicon-and-metal-containing material 515 may further include boron, carbon, and/or nitrogen. Exemplary boron-containing precursor may include borane (BH₃), diborane (B₂H₆), boron trichloride (BCl₃), or any other boron-containing precursor that may be useful in semiconductor processing. Exemplary carbon-containing precursor may include propene (C₃H₆) or any other carbon-containing precursor that may be useful in semiconductor processing. Exemplary nitrogen-containing precursor may include diatomic nitrogen (N₂), ammonia (NH₃), or any other carbon-containing precursor that may be useful in semiconductor processing. Additionally, one or more carrier gases or inert gases may be provided with the one or more deposition precursors which may serve as diluting gases. For example, diatomic hydrogen (H₂), argon (Ar), xenon (Xe), diatomic nitrogen (N₂), or any other carrier gas or inert gas useful in semiconductor processing may be provided.

As previously discussed, the one or more deposition precursors may be combined and interact prior to reaching the processing region. The present technology may utilize silicon-and-halogen-containing precursors that may not spontaneously react with the metal-containing precursor. Conventional technologies have struggled to form silicon-and-metal-containing materials due to spontaneous interaction between silicon-containing precursors and metal-containing precursors. With such a reaction, a large amount of residue will be created, and the layer of material will either have very low metal concentration or very high metal concentration. By utilizing more compatible precursors, such as silicon-containing precursors including a halogen, spontaneous reaction between the one or more deposition precursors may be reduced and/or eliminated. By utilizing silicon-and-halogen-containing precursors, the present technology may also permit a tunable process window in which the metal concentration in the deposited material can be a wider range compared to conventional technologies.

In embodiments, the method 400 may include cycling a flow rate of the one or more deposition precursors during the deposition. For example, a flow rate of the metal-containing precursor may be greater than a flow rate of the silicon-and-hydrogen-containing precursor during a first period of time. After an amount of deposition, the flow rate of the metal-containing precursor may be less than a flow rate of the silicon-and-hydrogen-containing precursor during a second period of time. By cycling the flow rates of the one or more deposition precursor, such as the silicon-and-halogen-containing precursor and the metal-containing precursor, the extent of gas-phase reactions between deposition precursors may be reduced. In embodiments, each period of time may be the same or may be different, and may range from about 0.05 seconds to about 2 seconds.

As previously discussed, some embodiments may include plasma-enhanced deposition operations, and plasma effluents of the one or more deposition precursors may be generated. The plasma power, which may be a 13.56 MHz source power, may impact the amount of metal concentration in the deposited material, with higher plasma powers generating more silicon to be incorporated into the material. Accordingly, depending on the desired metal concentration, the plasma power may be greater than or about 200 W, and may be greater than or about 300 W, greater than or about 400 W, greater than or about 500 W, greater than or about 750 W, greater than or about 1,000 W, greater than or about 1,250 W, greater than or about 1,750 W, greater than or about 2,000 W, or more. Similarly, for materials with reduced metal incorporation, the plasma power may be maintained at less than or about 3,000 W, and may be maintained at less than or about 2,750 W, less than or about 2,500 W, less than or about 2,250 W, less than or about 2,000 W, less than or about 1,750 W, less than or about 1,500 W, less than or about 1,250 W, less than or about 1,000 W, or less.

The temperatures of the substrate 505 may impact the deposition. For example, in some embodiments during deposition, the substrate 505, pedestal, and or semiconductor processing chamber may be maintained at a temperature of greater than or about 50° C., and may be maintained at a temperature of greater than or about 100° C., greater than or about 150° C., greater than or about 200° C., greater than or about 250° C., greater than or about 300° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., or greater. By performing the deposition according to some embodiments of the present technology, metal incorporation in the layer of silicon-and-metal-containing material 515 may be controlled. Increased temperatures may result in more silicon incorporation in the layer of silicon-and-metal-containing material 515 and, therefore, reduced metal incorporation. Conversely, reduced temperatures may result in less silicon incorporation in the layer of silicon-and-metal-containing material 515 and, therefore, increased metal incorporation. Accordingly, in some embodiments, the substrate 505, pedestal, and or semiconductor processing chamber may be maintained at a temperature of less than or about 600° C., and may be maintained at a temperature of less than or about 575° C., less than or about 550° C., less than or about 525° C., less than or about 500° C., less than or about 475° C., less than or about 450° C., less than or about 425° C., less than or about 400° C., less than or about 375° C., less than or about 350° C., less than or about 300° C., less than or about 250° C., less than or about 200° C., less than or about 150° C., less than or about 100° C., less than or about 50° C., or less.

As noted above, the present technology may increase the deposition rate of layers of silicon-and-metal-containing materials, which may increase throughput and reduce queue times. For example, the deposition may be performed at a pressure of greater than or about 0.1 Torr, greater than or about 0.5 Torr, greater than or about 1 Torr, greater than or about 5 Torr, greater than or about 6 Torr, greater than or about 7 Torr, greater than or about 8 Torr, greater than or about 9 Torr, greater than or about 10 Torr, greater than or about 15 Torr, greater than or about 30 Torr, greater than or about 50 Torr, or more. Similarly, the deposition may be performed at a pressure of less than or about 100 Torr, less than or about 75 Torr, less than or about 50 Torr, less than or about 40 Torr, less than or about 30 Torr, less than or about 20 Torr, less than or about 15 Torr, less than or about 10 Torr, or less.

The present technology may deposit the layer of silicon-and-metal-containing material 515 at a rate of greater than or about 500 Å/m, such as greater than or about 525 Å/m, greater than or about 550 Å/m, greater than or about 575 Å/m, greater than or about 600 Å/m, greater than or about 625 Å/m, greater than or about 650 Å/m, greater than or about 675 Å/m, greater than or about 700 Å/m, greater than or about 725 Å/m, greater than or about 750 Å/m, or more.

By performing operations according to embodiments of the present technology, metal may be included in the layer of silicon-and-metal-containing material 515 in any amount or concentration. In embodiments, metal may be included in the layer of silicon-and-metal-containing material 515 at greater than or about 1 at. %, and in some embodiments may be included at greater than or about 2 at. %, greater than or about 3 at. %, greater than or about 4 at. %, greater than or about 5 at. %, greater than or about 6 at. %, greater than or about 7 at. %, greater than or about 8 at. %, greater than or about 9 at. %, greater than or about 10 at. %, greater than or about 11 at. %, greater than or about 12 at. %, greater than or about 13 at. %, greater than or about 14 at. %, greater than or about 15 at. %, greater than or about 16 at. %, greater than or about 17 at. %, greater than or about 18 at. %, greater than or about 19 at. %, greater than or about 20 at. %, greater than or about 25 at. %, greater than or about 30 at. %, greater than or about 40 at. %, greater than or about 50 at. %, greater than or about 60 at. %, greater than or about 70 at. %, greater than or about 80 at. %, greater than or about 90 at. %, or more. However, metal incorporation may reduce transparency as well as hardness, and thus in some embodiments the metal concentration may be maintained at less than or about 50 at. %, less than or about 45 at. %, less than or about 40 at. %, less than or about 35 at. %, less than or about 30 at. %, less than or about 25 at. %, less than or about 20 at. %, or less. In embodiments, the layer of silicon-and-metal-containing material 515 may be free of fluorine, oxygen, or both.

The present technology may permit high etch selectivity to underlying materials by incorporating increased metal concentration in the layer of material. Additionally, the present technology may provide materials with smooth morphology. Increased material adhesion may be achieved by optional pre-treatment and/or seed layer formation. Accordingly, the present technology provides silicon-and-metal-containing materials that may optionally include one or more of boron, carbon, or nitrogen for hardmask applications.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing deposition precursors to a processing region of a semiconductor processing chamber, wherein the deposition precursors comprise a silicon-and-halogen-containing precursor and a metal-containing precursor, and wherein a substrate is housed within the processing region;
generating plasma effluents of the deposition precursors; and
forming a layer of silicon-and-metal-containing material on the substrate.

2. The semiconductor processing method of claim 1, wherein the silicon-and-halogen-containing precursor comprises silicon tetrafluoride (SiF₄).

3. The semiconductor processing method of claim 1, wherein the metal-containing precursor comprises one or more of tungsten, molybdenum, cobalt, tantalum, ruthenium, titanium, rhenium, hafnium, or zirconium.

4. The semiconductor processing method of claim 1, wherein the metal-containing precursor further comprises a halogen.

5. The semiconductor processing method of claim 1, wherein the deposition precursors further comprise one or more of a boron-containing precursor, a carbon-containing precursor, or a nitrogen-containing precursor.

6. The semiconductor processing method of claim 1, further comprising:
cycling a flow rate of the deposition precursors, wherein a flow rate of the metal-containing precursor is greater than a flow rate of the silicon-and-hydrogen-containing precursor during a first period of time, and wherein the flow rate of the metal-containing precursor is less than a flow rate of the silicon-and-hydrogen-containing precursor during a second period of time.

7. The semiconductor processing method of claim 1, wherein the layer of silicon-and-metal-containing material is characterized by a metal concentration of greater than or about 20 at. %.

8. The semiconductor processing method of claim 1, further comprising:
pre-treating the substrate prior to forming the layer of silicon-and-metal-containing material.

9. The semiconductor processing method of claim 8, wherein pre-treating the substrate comprises:
providing a nitrogen-containing precursor to the processing region of the semiconductor processing chamber;
generating plasma effluents of the nitrogen-containing precursor; and
contacting the substrate with the plasma effluents of the nitrogen-containing precursor.

10. The semiconductor processing method of claim 8, further comprising:
subsequent pre-treating the substrate, forming a seed layer on the substrate.

11. The semiconductor processing method of claim 10, wherein the seed layer comprises an amorphous boron-containing material.

12. A semiconductor processing method comprising:
providing deposition precursors to a processing region of a semiconductor processing chamber, wherein the deposition precursors comprise a silicon-and-halogen-containing precursor and a metal-containing precursor, and wherein a substrate is housed within the processing region;
generating plasma effluents of the deposition precursors, wherein plasma effluents of the deposition precursors are generated at a plasma power of greater than or about 200 W; and
forming a layer of silicon-and-metal-containing material on the substrate.

13. The semiconductor processing method of claim 12, wherein plasma effluents of the deposition precursors are generated at a plasma power of less than or about 2,000 W.

14. The semiconductor processing method of claim 12, wherein the layer of silicon-and-metal-containing material is free of fluorine, oxygen, or both.

15. The semiconductor processing method of claim 12, further comprising:
prior to providing the deposition precursors, pre-treating the substrate and forming a seed layer on the substrate.

16. The semiconductor processing method of claim 12, wherein a temperature within the processing region is maintained at less than or about 600° C.

17. The semiconductor processing method of claim 12, wherein a pressure within the processing region is maintained at less than or about 50 Torr.

18. A semiconductor processing method comprising:
providing a silicon-containing precursor and a metal-containing precursor to a processing region of a semiconductor processing chamber, wherein a substrate is housed within the processing region; and
forming a layer of silicon-and-metal-containing material on the substrate, wherein the layer of silicon-and-metal-containing material is characterized by a metal concentration of greater than or about 20 at. %.

19. The semiconductor processing method of claim 18, wherein the silicon-containing precursor comprises silicon tetrafluoride (SiF₄) and the metal-containing precursor comprises tungsten hexafluoride (WF₆).

20. The semiconductor processing method of claim 18, wherein the layer of silicon-and-metal-containing material is formed at a rate of greater than or about 500 Å/m.
